(19) United States
(12) Patent Application Publication
(10) Pub. No.: US 2023/0151948 A1
(43) Pub. Date: May 18, 2023

(54) MICRO-LIGHTGUIDE FOR MICRO-LED

(71) Applicant: PLESSEY SEMICONDUCTORS LIMITED, Plymouth (GB)

(72) Inventor: Samir MEZOUARI, Plymouth (GB)

(73) Assignee: PLESSEY SEMICONDUCTORS LIMITED, Plymouth (GB)

(21) Appl. No.: 17/917,426

(22) PCT Filed: Apr. 6, 2021
(86) PCT No.: PCT/EP2021/058953

§ 371 Date: Oct. 6, 2022

(30) Foreign Application Priority Data
Apr. 8, 2020 (GB) 2005224.7

(51) Int. Cl. F21V 13/10; F21V 7/04

(52) U.S. Cl. CPC F21V 13/10; F21V 7/041; F21Y 2115/10

(57) ABSTRACT

A method for fabricating a frusto-conical micro-lightguide for collimation of light emitted from micro-LEDs. The method comprises depositing a layer of UV-curable material onto a substrate. A first part of the layer is selectively cured using UV light having a conical irradiation profile to define a shape of the frusto-conical micro-lightguide. The UV-curable material is developed to remove one of the first part of the layer and a second part of the layer, wherein the second part of the layer is uncured.

### FIELD OF THE DISCLOSURE

The disclosure relates to the field of light emitting diodes (LEDs). More particularly, the present disclosure relates to methods of improving emission efficiency of LEDs.

### BACKGROUND

LEDs convert electrical energy into optical energy. In semiconductor LEDs this usually occurs via electron-hole transitions when recombination of electrons, from an n-doped semiconductor layer, and holes, from a p-doped semiconductor layer, occurs. The area in which the main light emission takes place may be referred to as the active region. The light generated at a quantum well in an LED may be emitted in all directions but the change in refractive index at a boundary of the LED material means that only emitted light rays with an angle of incidence within a critical angle range (an escape range) can be emitted. Even some light within the escape range may be lost due to small Fresnel losses with change of angle. If the angle of incidence is outside the escape range, total internal reflection may occur. One major challenge in LED production is to improve extraction efficiency, and to capture as much of the emitted light as possible.

Some LEDs emit directly to air. An emission efficiency may be said to be the number of photons that escape the LED into the air relative to the total number of photons generated. The refractive index of the substrate material is generally much higher than that of air, so only light that is incident at an angle close to the normal of the exit surface can escape. Often LEDs are coupled to light collection devices such as projection lenses instead of directly to air. In such cases there may be further losses at an interface between the LED and the light collection device due to some light emitted by the LED diverging at an angle such that it does not reach the interface with the light collection device. Emission efficiency then depends both on the proportion of photons that escape the LED and on the proportion of those escaped photons that are captured by the light collection device.

The efficiency in capturing the escaped photons may depend on size of the divergent light angle (a solid angle formed by a half-power beam width of the emitted light) compared to the light collection angle (a solid angle through which at least half of the available photons are captured by a light collection device). LEDs emit light in an angular distribution close to a Lambertian emission with a full-width half maximum (FWHM) of 120 degrees. The acceptance angle of a lens may be determined by its F number, which for a typical projection lens might be F/2.5 or F/3 giving acceptance angles 11.3° and 9.5° respectively. Only 2.7% of light emitted by a Lambertian LED is within ±9.5°, so 97.3% of light is lost by virtue of not passing into the lens. Thus there is a need to increase efficiency of emission from the LED and to collimate the emitted light.

Existing solutions may rely either on precise etching of the LED semiconductor material or shaping of the chip mesa of an LED device. The shape of a mesa may be designed such that the light emitted from the active region is reflected towards the emission surface in such a way that more photons have angles of incidence which allow them to be transmitted, and may also be selected to focus the beam. For example, an integrated transparent conductive layer may be formed integrally with the LED structure during fabrication, and etched to form a cap which enhances light extraction (US2015008392 A1). A convex optical structure may also be formed by laser ablation on the side of the substrate opposite to the light emitting region, which reflects light towards the light emitting surface such that it is transmitted and collimated (US2018083170 A1). Rather than shaping the LED material itself, the chip mesa can be shaped into a parabolic structure in which the active layer sits, so that light incident on the sidewalls is reflected towards the light emitting surface opposed to the mesa (US2015236201 A1 and US2017271557 A1). Etching the mesa risks damaging the active layer, and it may be difficult to achieve a smooth enough finish for high degrees of collimation.

Micro-LEDs are used for high-resolution displays, and with ever decreasing dimensions it may be increasingly difficult to etch features with sufficient precision to collimate light effectively. The inherently small dimensions of the semiconductor materials used to collimate the emitted light may also result in poor levels of luminance uniformity. It is an object of the present invention to provide a scalable design which provides an accurate emission angle as well as high levels of angular and brightness uniformity.

### SUMMARY OF THE DISCLOSURE

Against this background, there is provided:

A method for fabricating a frusto-conical micro-lightguide for collimation of light emitted from micro-LEDs, comprising:
depositing a layer of UV-curable material onto a substrate;
selectively curing a first part of the layer using UV light having a conical irradiation profile to define a shape of the frusto-conical micro-lightguide;
developing the UV-curable material to remove one of the first part of the layer and a second part of the layer, wherein the second part of the layer is uncured.

In this way, it is possible to fabricate precise micro-lightguides at small scales in order to collimate light emitted from a micro-LED so as to increase a proportion of extracted light.

The second part of the layer may be removed and the first part of the layer may comprise the frusto-conical micro-lightguide.

Advantageously, using the first part of the UV-curable material as the frusto-conical micro-lightguide requires relatively few processing steps and is a scalable process.

The first part of the layer may be removed and the second part of the layer may comprise a frusto-conical recess that defines the shape of the frusto-conical micro-lightguide.

Advantageously, a negative resist may be used instead of a positive resist so the process is flexible.

The method may further comprise depositing a lightguide material in the frusto-conical recess and removing the second part of the layer, such that the lightguide material comprises the frusto-conical micro-lightguide.

In this way, a wider range of materials may be used for the frusto-conical micro-lightguide since the lightguide material is not necessarily UV-curable.

The frusto-conical micro-lightguide may comprise a first planar surface and a second planar surface, wherein the first planar surface has a smaller area than the second planar surface.

In this way, light that is transmitted through the first planar surface may be incident on a sidewall of the frusto-conical micro-lightguide and may be reflected such that the angle of the reflected light ray to a central axis of the frusto-conical micro-lightguide may be smaller than the angle of the incident light ray to a central axis of the frusto-conical micro-lightguide. Thus a light beam transmitted through the first planar surface is collimated and a narrower light beam is emitted from the second planar surface.

The method may further comprise fabricating an array of micro-lightguides.

In this way, light from each micro-LED in an array of micro-LEDs may be collimated.

The conical irradiation profile may take a form of a substantially inverted cone and may be achieved by transmitting the UV light through a mask that is moving in a circular trajectory, such that the first planar surface of the frusto-conical micro-lightguide is proximate the substrate.

In this way, a part of the UV-curable material that is frusto-conical in shape may be cured.

The substrate may be a processed wafer comprising a plurality of micro-LEDs.

Advantageously, the frusto-conical micro-lightguides are fabricated directly onto the micro-LEDs and so the frusto-conical micro-lightguides do not need to be aligned with the micro-LEDs after fabrication.

The mask may comprise one or more circular apertures.

In this way, the irradiation profile of light transmitted through the mask may have a conical profile when the mask is moved in a circular trajectory.

The conical irradiation profile may be achieved by collimation of the UV light such that the second planar surface of the frusto-conical micro-lightguide is proximate the substrate.

In this way, the frusto-conical micro-lightguide may be fabricated separately to the micro-LEDs.

The collimation may be achieved using one or more micro-lenses.

In this way, the UV light that is transmitted through the micro-lenses has a conical profile.

The substrate may be a transparent material such as glass or sapphire.

Advantageously, the frusto-conical micro-lightguide may then be coupled to a micro-LED and the substrate does not need to be removed.

The micro-lightguides may be coupled to an array of micro-LEDs.

In this way, light from each micro-LED in an array of micro-LEDs may be collimated.

The angle of a sidewall of the frusto-conical micro-lightguide to a central axis of the frusto-conical micro-lightguide may preferably be between 10° and 18°, wherein the central axis of the frusto-conical micro-lightguide passes through a central point of the first planar surface and a central point of the second planar surface.

In this way, the light that is transmitted through the frusto-conical micro-lightguide may be collimated.

The central axis of the frusto-conical micro-lightguide may be aligned with a central axis of a micro-LED.

In this way, efficiency of light collection by the frusto-conical micro-lightguide is increased.

The micro-lightguide may further comprise a reflective coating.

In this way, light cross-talk between adjacent frusto-conical micro-lightguides is reduced.

The UV-curable resist material may be deposited by spin coating.

Advantageously, this process is scalable and achieves a layer that is uniform.

The first planar surface has a characteristic dimension that may be 50% of a characteristic dimension of the second planar surface.

In this way, an appropriate angle of the sidewall of the frusto-conical micro-lightguide is achieved.

The characteristic dimension of the second planar surface may be equal to a characteristic dimension of the frusto-conical micro-lightguide that is parallel to the central axis of the frusto-conical micro-lightguide.

In this way, an appropriate level of collimation of a light beam is achieved.

The characteristic dimension of the first planar surface may be 60 % larger than a characteristic dimension of the micro-LED.

The characteristic dimension of the first planar surface may preferably be 70 % larger than the characteristic dimension of the micro-LED.

In this way, efficiency of light collection by the frusto-conical micro-lightguide is increased.

### BRIEF DESCRIPTION OF THE DRAWINGS

A specific embodiment of the disclosure will now be described, by way of example only, with reference to the accompanying drawings in which:

FIG. 1 shows a schematic diagram of a frusto-conical micro-lightguide with exemplary light rays in accordance with an embodiment of the disclosure.

FIG. 2 shows a schematic cross-section of an array of frusto-conical micro-lightguides coupled to an array of light sources with exemplary light-rays, in accordance with an embodiment of the disclosure.

FIG. 3 shows a perspective view of an array of frusto-conical micro-lightguides coupled to an array of light sources, in accordance with an embodiment of the disclosure.

FIG. 4 shows a cross-section of a frusto-conical micro-lightguide coupled to a micro-LED with exemplary light rays, in accordance with an embodiment of the disclosure.

FIG. 5 shows a cross-section of an array of frusto-conical micro-lightguides coupled to an array micro-LEDs, in accordance with an embodiment of the disclosure.

FIG. 6 shows a plan view of an array of frusto-conical micro-lightguides coupled to an array of micro-LEDs, in accordance with an embodiment of the disclosure.

FIG. 7 shows data derived from simulations of the angular profile of light emitted from a micro-lightguide, in accordance with an embodiment of the disclosure. FIG. 7A shows the intensity as a function of angle as a polar plot, and FIG. 7B shows intensity as a function of angle on a linear scale.

FIG. 8 shows a cross-section of an array of frusto-conical micro-lightguides coated with a reflective material and coupled to an array of micro-LEDs, in accordance with an embodiment of the disclosure.

FIG. 9 shows simple schematic diagram indicating the cured and uncured parts of a UV-curable material during the fabrication process of a frusto-conical micro-lightguide, in accordance with an embodiment of the disclosure. FIG. 9A shows a layer of UV-curable material on a substrate. FIGS. 9B and 9D show the cured and uncured parts of the UV-curable material. FIGS. 9C and 9E show the frusto-conical cured parts of the UV-curable material on the substrate after developing the UV-curable material to remove the uncured parts of the UV-curable material.

FIG. 10 shows the steps of fabricating an array of frusto-conical micro-lightguides using a moving mask, in accordance with an embodiment of the disclosure. FIG. 10A shows a layer of UV-curable material on an array of micro-LEDs. FIG. 10B shows a moving mask and incident UV light on the UV-curable material. FIG. 10C shows the frusto-conical micro-lightguides left on the micro-LEDs after development of the UV-curable material to remove the uncured parts of the UV-curable material.

FIG. 11 shows the steps of fabricating a frusto-conical micro-lightguide using UV light collimated via a micro-lens, in accordance with an embodiment of the disclosure. FIG. 11A shows the UV light collimated into a conical irradiation profile using a micro-lens, wherein the UV light is incident on UV-curable material on a substrate. FIG. 11B shows the frusto-conical micro-lightguide left on the micro-LEDs after development of the UV-curable material to remove the uncured parts of the UV-curable material.

FIG. 12 shows a perspective view of an array of frusto-conical micro-lightguides on a substrate, in accordance with an embodiment of the disclosure.

FIG. 13 shows a cross-section of an array of frusto-conical micro-lightguides on a substrate coupled to an array of micro-LEDs, in accordance with an embodiment of the disclosure.

### DETAILED DESCRIPTION

According to an embodiment of this disclosure, a micro-lightguide 100 for collimation of light emitted by a micro-light emitting diode (micro-LED) is provided. A method for fabricating the micro-lightguide 100 is also provided.

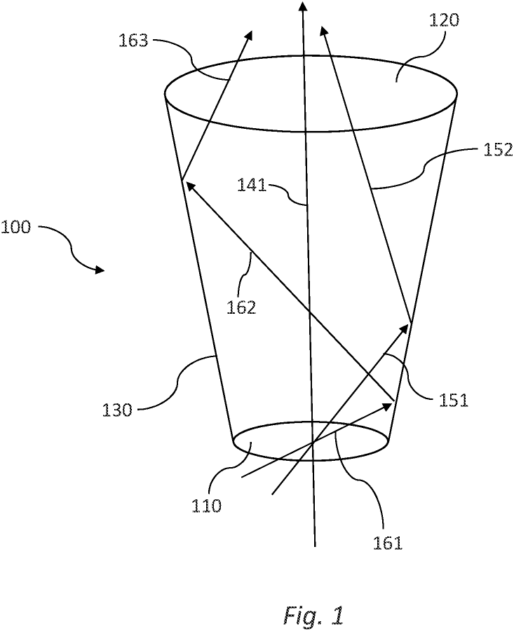

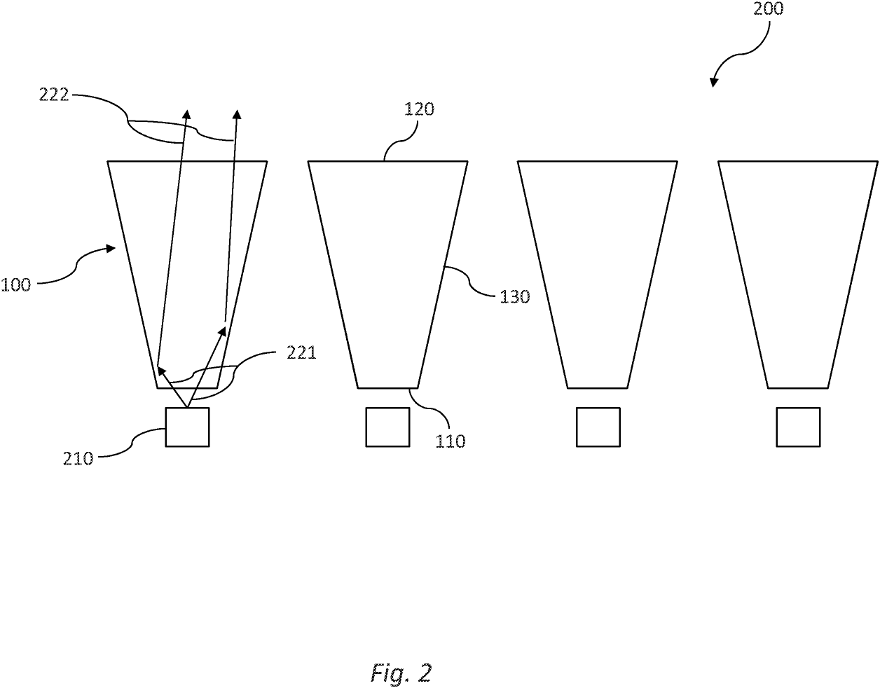

With reference to FIG. 1, a micro-lightguide 100 comprises a first planar surface 110 and a second planar surface 120 opposing the first planar surface 110, wherein the first planar surface 110 has a smaller area than the second planar surface 120. The first planar surface 110 and second planar surface 120 may both be circular. The micro-lightguide 100 may comprise a sidewall 130 extending between the first planar surface 110 and the second planar surface 120. The sidewall 130 may be curved. Thus, the micro-lightguide 100 may have a frusto-conical shape. The micro-lightguide 100 may be fabricated from a material that is transparent to light in the visible spectrum. An incident light ray that is incident on the first planar surface 110 may be transmitted through the first planar surface 110. Depending on the angle of incidence of the incident light ray on the first planar surface 110, the transmitted light ray may transmit through the micro-lightguide so as to be incident on the second planar surface 120. Transmission through the micro-lightguide 100 may either be direct without reflecting off any part of the sidewall 130 or may include one or more reflections off the sidewall 130 by total internal reflection.

First, second and third exemplary transmitted light rays 141, 151 and 161 are shown in FIG. 1. The first transmitted light ray 141 is incident on the second planar surface 120 without having reflected off the sidewall 130 and is transmitted through the second planar surface 120, thus exiting the micro-lightguide 100. The second and third transmitted light rays 151 and 161 are reflected from the sidewall 130 via total internal reflection. The second transmitted light ray 151 may be reflected off the sidewall 130 as a first reflected light ray 152. The first reflected light ray 152 may be incident on the second planar surface 120 and may be transmitted, exiting the micro-lightguide 100. The angle of the first reflected light ray 152 to the central axis of the micro-lightguide 100 may be smaller than the angle of the second incident light ray 151 to the central axis of the micro-lightguide 100, wherein the central axis of the micro-lightguide 100 passes through the centre of the first planar surface 110 and through the centre of the second planar surface 120. The third transmitted light ray 161 may be incident on the sidewall 130 and reflected off the sidewall 130 as a second reflected light ray 162. The second reflected light ray 162 may then be incident on the sidewall 130 and reflected again as a third reflected light ray 163. The third reflected light ray 163 may then be incident on the second planar surface 120 and transmitted through the second planar surface 120 to exit the micro-lightguide 100. The angle of the third reflected light ray 163 to the central axis of the micro-lightguide 100 may be smaller than the angle of the third incident light ray 161 to the central axis of the micro-lightguide 100

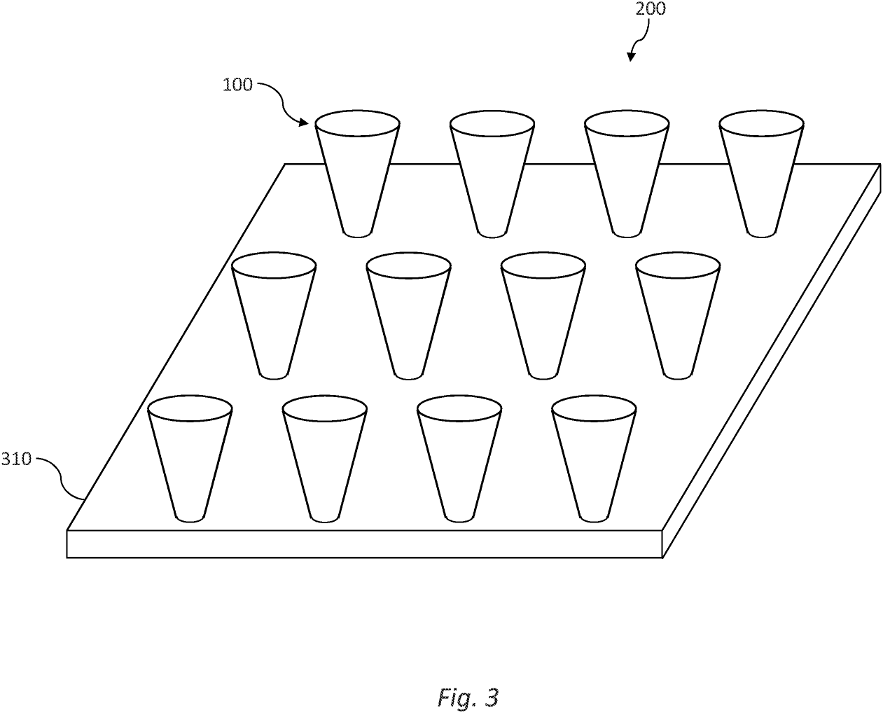

With reference to FIG. 2, the micro-lightguide 100 may be coupled to a light source 210. The light source 210 may be proximate to the first planar surface 110 such that light emitted by the light source is incident on the first planar surface 110. The light source may emit light in any direction and may emit light from any point on the light source, but in FIG. 2, for clarity of explanation, only two exemplary light rays 221 are shown which are emitted from a single point only. The light rays 221 are transmitted through the first planar surface 110 and are incident on the sidewall 130. The light rays 221 are reflected from the sidewall 130 via total internal reflection and are incident on the second planar surface 120, and transmitted through the second planar surface 120 to exit the micro-lightguide 100. The angle of the reflected light ray 222 to the central axis of the micro-lightguide 100 may be smaller than the angle of the incident light ray 221 to the central axis of the micro-lightguide 100. There may be a plurality of micro-lightguides 100 arranged in an array 200 such that each micro-lightguide 100 is coupled to a separate light source 210. The light source 210 may be a micro-LED.

With reference to FIG. 3, the array 200 of micro-lightguides 100 may be coupled to a substrate 310 comprising an array of light sources 210. The central axis of each micro-lightguide 100 may be aligned with the central axis of each light source 210. The micro-lightguides 100 may be arranged at a constant pitch.

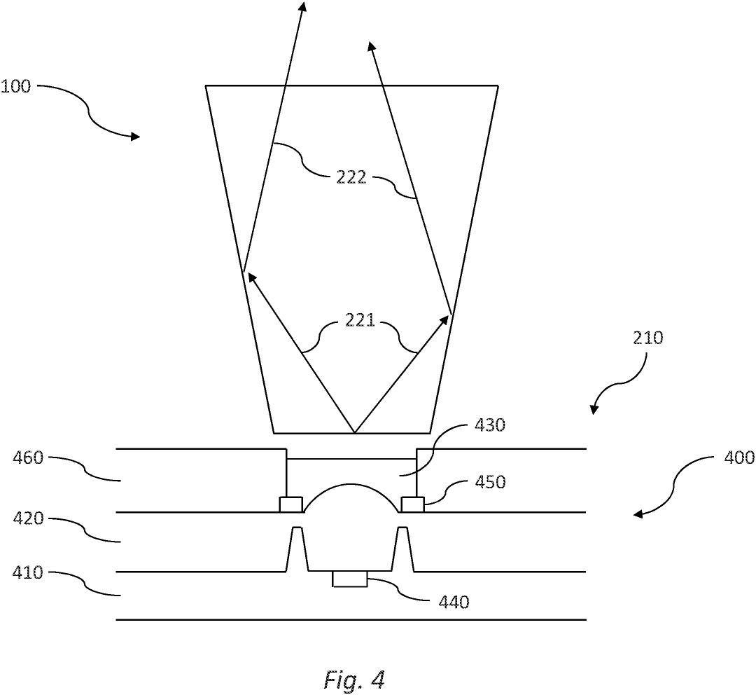

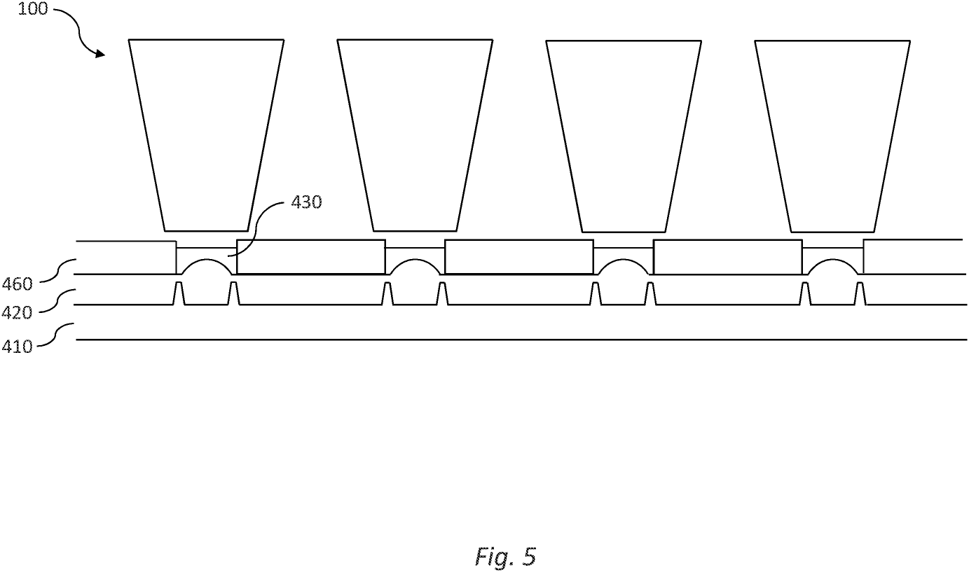

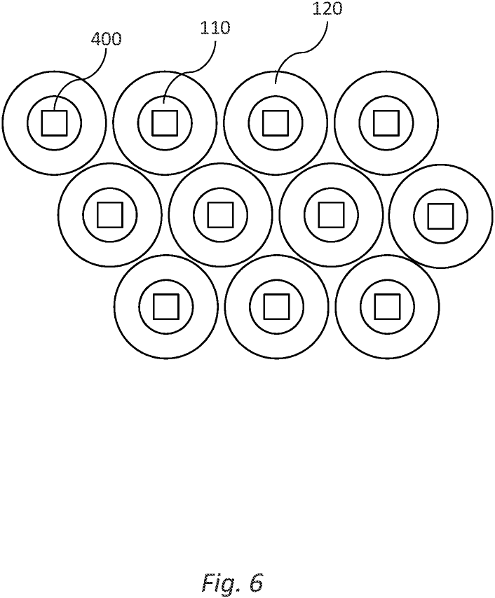

With reference to FIG. 4, the light source 210 may comprise a pixel 400 comprising a micro-LED. The micro-LED may comprise a substrate 410, a semiconductor material 420 provided on the substrate 410 and a capping material 430 provided on the semiconductor material 420. The semiconductor 420 is configured to emit light in response to an electric current, which may be applied using electrodes 440 and 450. In a certain embodiment, the substrate 410 may comprise a complementary metal-oxide-semiconductor (CMOS) and the semiconductor material 420 may comprise a monolithic InGaN LED. The monolithic InGaN LED may emit blue light, in which case the capping material 430 may be a clear transparent material for a blue pixel, and a colour converting material such as quantum dots or phosphor for red and green pixels. With reference also to FIG. 5, a plurality of pixels 400 may be provided and arranged in an array, and each pixel 400 of the plurality of pixels 400 may be coupled to a micro-lightguide 100. There may be a light blocking material 460 between each capping material 430 to prevent light cross talk between pixels. The light-blocking material 460 may absorb visible light and be photo-definable. A simplistic representation of an example of such an array is shown in plan view in FIG. 6.

In a certain embodiment, the characteristic dimension of the micro-lightguide 100 along its central axis may be 5 µm, a characteristic dimension of the first planar surface 110 may be 2.5 µm and a characteristic dimension of the second planar surface 120 may be 5 µm. The angle of the sidewall 130 to the central axis of the micro-lightguide is then 14°. The first planar surface 110 and second planar surface 120 may be circular, so the characteristic dimension of the first and second planar surfaces may be a diameter. The characteristic dimension of the first planar surface 110 may preferably be 60% larger than the characteristic dimension of the light-source 210. More preferably, the characteristic dimension of the first planar surface 110 may be 70% larger than the characteristic dimension of the light-source 210. The pitch of an array 200 of micro-lightguides 100 may be 8 µm, and the pitch of an array of light sources 210 may be 8 µm.

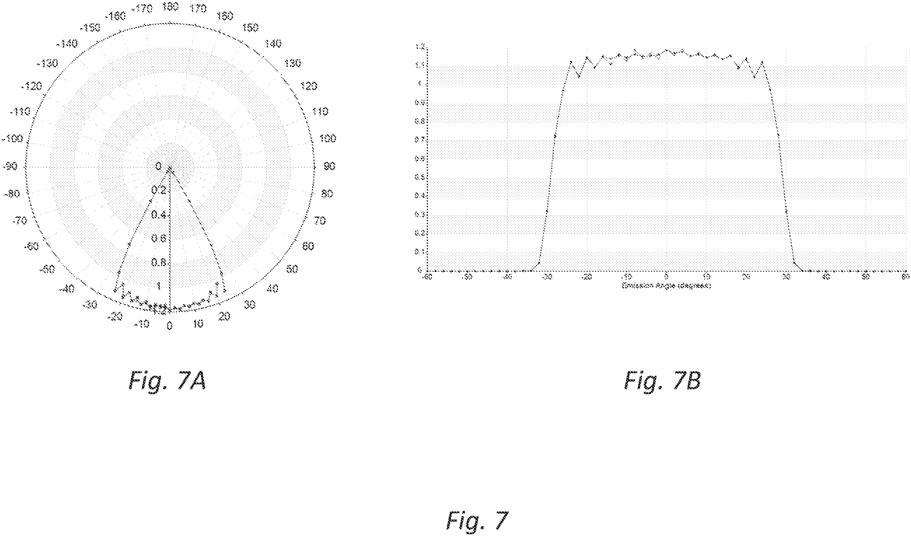

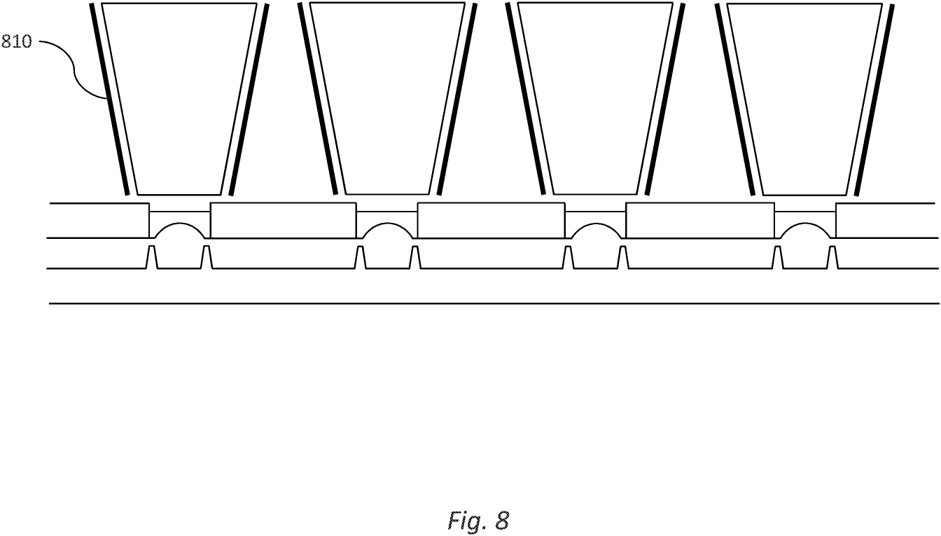

With reference to FIG. 7, the profile of light emitted from the second planar surface 120 of the micro-lightguide 100 is shown. The data plotted in FIG. 7 are derived from simulation results for a micro-lightguide 100 with a characteristic dimension along its central axis of 5 µm, a diameter of the circular first planar surface 110 of 2.5 µm and a diameter of the circular second planar 120 surface of 5 µm. The light from the light source 210 that is incident on the first planar surface 110 has a Lambertian distribution with a full width half maximum (FWHM) of 120°, and the light emitted from the second planar surface 120 has a full width half maximum of 57°. FIG. 7A shows the intensity of the light plotted with angle on a polar graph, and FIG. 7B shows the intensity plotted against angle on a linear scale.

With reference to FIG. 8, the micro-lightguides 100 might be coated with a reflective material 810 to prevent light cross-talk between micro-lightguides 100. In a certain embodiment, the reflective material 810 may be Aluminium or Silver.

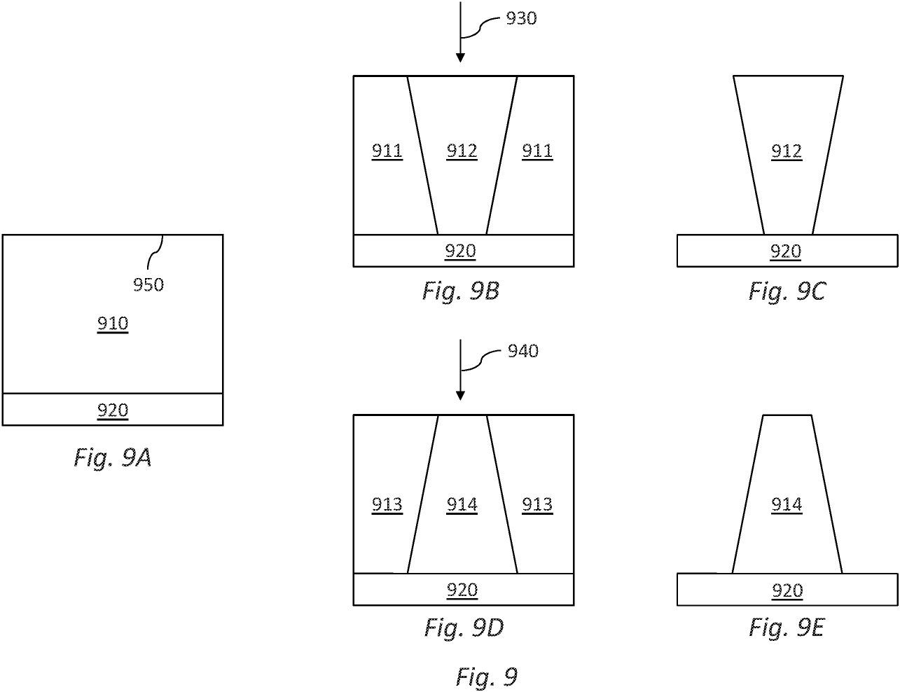

With reference to FIG. 9, the micro-lightguide 100 may be fabricated by depositing a layer of UV-curable material 910 onto a substrate 920 (FIG. 9A). UV light 930 or 940 having a conical irradiation profile is incident on a first surface 950 of the UV-curable material 910 such that the UV light 930, 940 selectively cures a first part 912 or 914 of the UV-curable material 910. The UV-curable material 910 is then developed to remove one of the first, cured part (912 or 914) and a second, uncured part (911 or 913) of the layer such that the remaining part defines the shape of a frusto-conical micro-lightguide. In the example shown in FIG. 9, the second, uncured part 911 or 913 of the UV-curable material 910 is removed such that the first part 912 or 914 of the UV-curable material 910 remains as a frusto-conical micro-lightguide 100. The frusto-conical micro-lightguide may have its central axis perpendicular to the plane of the substrate 920, but may have either its first planar surface 110 adjacent to the substrate 920 (resulting from a conical irradiation profile similar to an inverted cone) or its second planar surface 120 adjacent to the substrate 920 (resulting from a conical irradiation profile similar to a cone). FIGS. 9B and 9C show the process wherein the UV light 930 has a conical irradiation profile such that the irradiation profile is narrower at the substrate 920 than at first surface 950 of the UV-curable material 910, so after fabrication the first planar surface 110 is adjacent to the substrate 920. FIGS. 9D and 9E show the process wherein the UV light 940 has a conical irradiation profile such that the irradiation profile is wider at the substrate 920 than at first surface 950 of the UV-curable material 910, so after fabrication the second planar surface 120 is adjacent to the substrate 920. In a certain other embodiment, the cured part 912 or 914 of the UV-curable material 910 may be removed such that the remaining uncured part 911 or 913 comprises a recess that defines a shape of the frusto-conical micro-lightguide. A lightguide material may be deposited in the recess and the uncured part 911 or 913 of the UV-curable material 910 may be removed, such that the remaining lightguide material comprises a frusto-conical micro-lightguide 100.

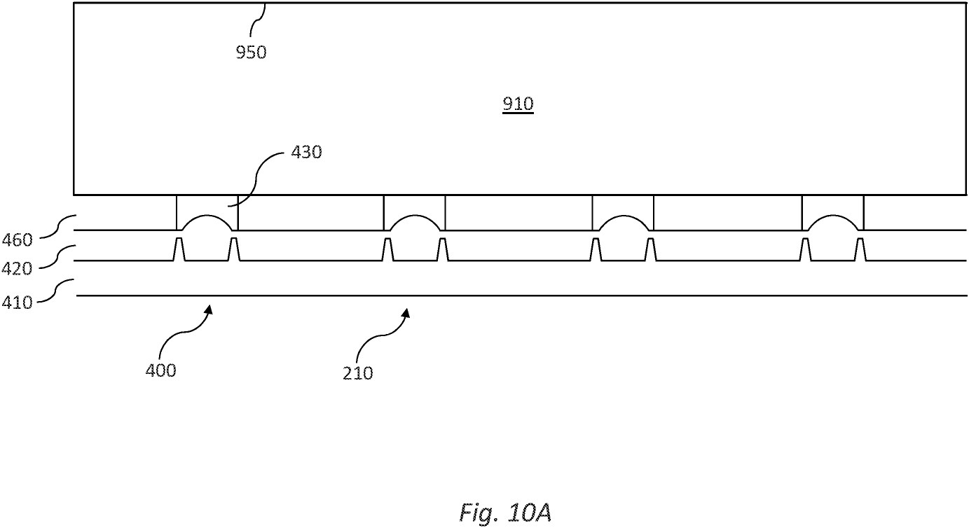

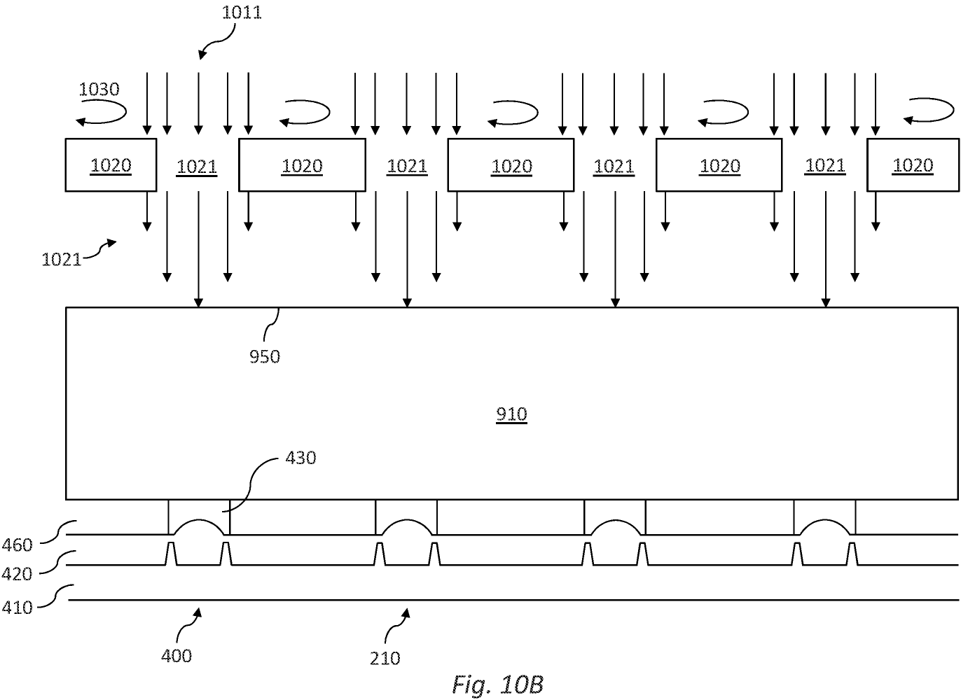

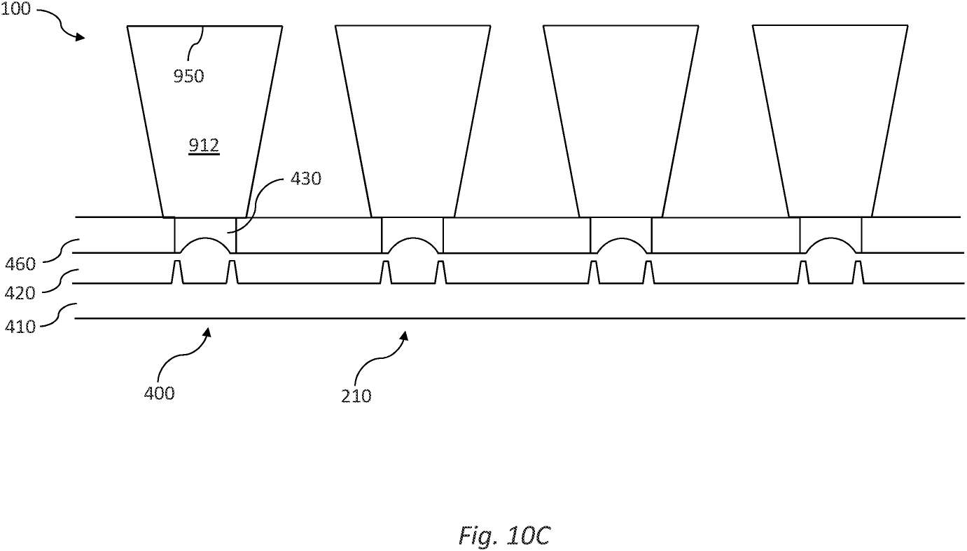

In a first embodiment, the substrate 920 may comprise an array 310 of light-sources 210. The UV-curable material 910 may be deposited directly onto an array of light-sources 210. With reference to FIG. 10A the light-sources 210 are shown as pixels 400 comprising micro-LEDs, as shown in FIG. 4. The UV-curable material 910 may be deposited by spin coating. With reference to FIG. 10B, UV light 1011 is incident on a mask 1020 at a normal to the plane of the mask 1020, wherein the plane of the mask 1020 is parallel to the substrate 920 and to the UV-curable material 910. The mask may have a plurality of apertures 1021, the central axis of each aperture 1021 being aligned with a central axis of a pixel 400. Each aperture 1021 may be circular. The mask 1020 is moved with a circular trajectory 1030 that is in the plane of the mask 1020, such that the UV light 1011 that is transmitted through the mask has an inverted conical irradiation profile. The UV light 1011 is incident on the first surface 950 of the UV-curable material 910. The inverted conical irradiation profile has highest intensity at the centre of the profile and lowest intensity at the edge of the profile. The highest intensity is constant over an area equal to the area of the first planar surface, and the central axis of the conical irradiation profile is aligned with the central axis of the pixel 400. The widest part of the irradiation profile has the same area as the second planar surface 120. The penetration depth of the curing of the UV-curable material 910 is a function of the intensity of the radiation profile, so the cured part 912 of the UV-curable material has a frusto-conical shape. The cured part 912 of the UV-curable material has a cross-sectional area adjacent to the substrate 920 equal to the area of the first planar surface 110 and a cross-sectional area at the first surface 950 equal to the area of the second planar surface. In a certain embodiment, the un-cured part 911 of the UV-curable material 910 is removed and the cured part 912 of the UV-curable material comprises frusto-conical micro-lightguides that are left on the substrate 920, as shown in FIG. 10C. In a certain embodiment, the cured part 912 of the UV-curable material 910 is removed, leaving frusto-conical recesses in the uncured part 911, and a lightguide material is deposited in the frusto-conical recesses. The uncured part 911 of the UV-curable material 910 is then removed and the remaining lightguide material comprises frusto-conical micro-lightguides.

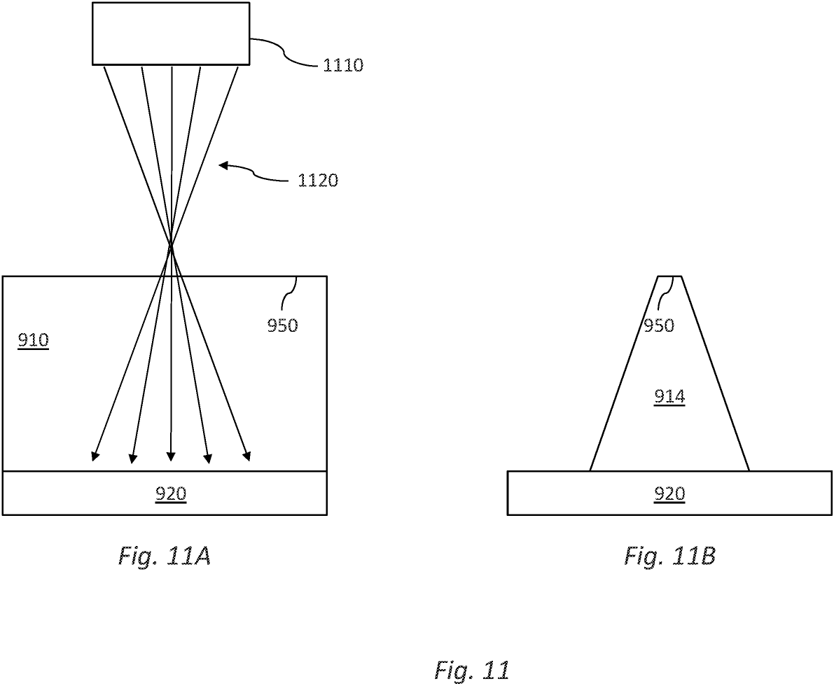

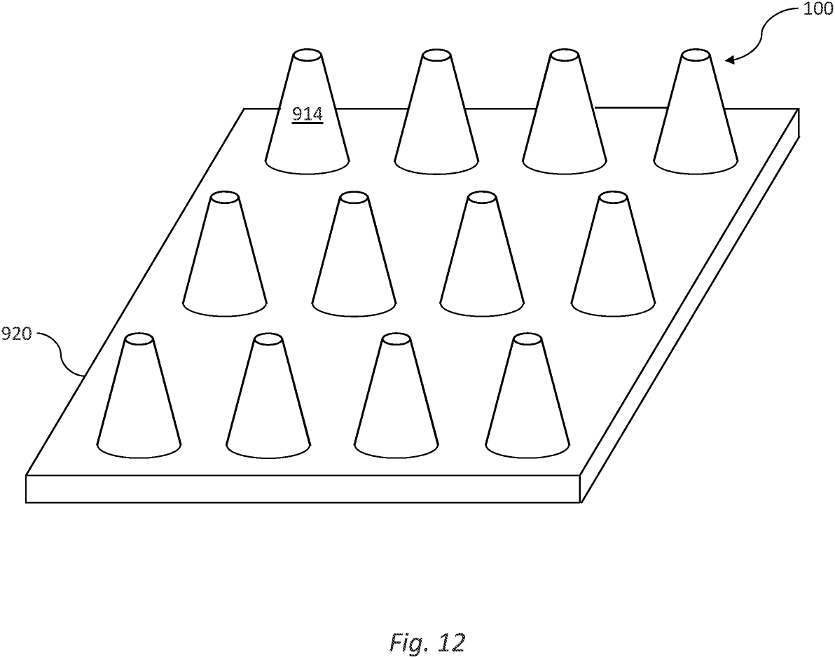

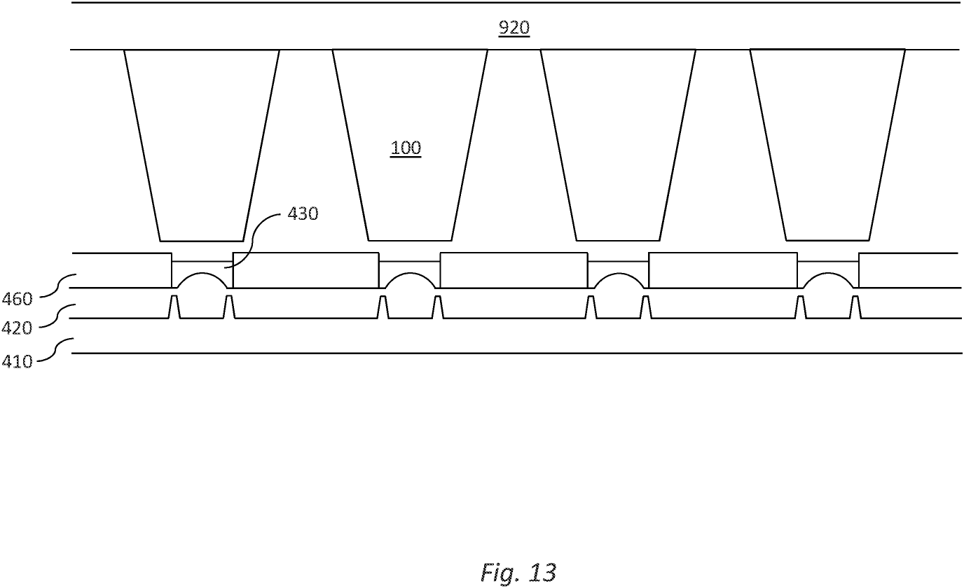

In a second embodiment, the substrate 920 may comprise a transparent material that is transparent to electromagnetic radiation with wavelengths in the visible spectrum. In a certain embodiment, the transparent material may be glass or sapphire. With reference to FIG. 11A, UV light is collimated using a micro-lens 1110, such that the UV light 1120 that is incident on the first surface 950 of the UV-curable material 910 has a conical profile within the UV-curable material 910. The conical profile has an area equal to the first planar surface 110 at the first surface 950 of the UV-curable material 910, and has an area equal to the second planar surface at the substrate 920. The UV-curable material 910 that is within the conical profile is cured, and the uncured part 913 may be removed. The cured part 914 has a frusto-conical shape and may be left on the substrate. In an embodiment, there may be an array of micro-lenses 1110 such that there is an array of cured parts 914. With reference to FIG. 12, a perspective view of a schematic of an array of cured parts 914 on a substrate 920 is shown, wherein the cured part 914 is a micro-lightguide 100. With reference to FIG. 13, the substrate 920 may be placed on an array of light-sources 210 such that each micro-lightguide 100 is coupled to a light-source 210. The central axis of a micro-lightguide 10 is aligned with the central axis of a light source 210. The first planar surface 110 is proximate to the light source 210. In an embodiment, the light source 210 may be a pixel 400 comprising a micro-LED. In a certain embodiment, the distance between the first planar surface 110 and the light source 210 may be smaller than 20% of an area of a light emitting area of the light source 210.

In a certain embodiment, the UV-curable material 910 may be absorbing of electromagnetic radiation with wavelengths in the UV region, and transparent to electromagnetic radiation with wavelengths in the visible spectrum. In a certain embodiment, the arithmetic average of the roughness profile of a surface of the micro-lightguide 100 may be less 20 nm. In a certain embodiment, the UV-curable material may have a refractive index of 1.555 for light with a wavelength of 589 nm. The UV-curable material may comprise or consist of OrmoClear®FX.

The UV-curable material 910 may be spin-coated onto the substrate 920. The thickness of the UV-curable material 910 may depend on the duration of the spin coating.

In a certain embodiment, in which the substrate 920 may comprise an array 310 of light sources 201, the substrate 920 may be spin-coated with the UV-curable material 910 and then baked at 80° C. for 2 minutes to improve adhesion to the substrate 920. The UV-curable material 910 may be exposed to UV light that is transmitted through a moving mask, wherein the mask moves in a circular trajectory such that the irradiance profile is similar to an inverted cone. The dose of IV exposure may be below 1000 mJ cm⁻² in order to achieve appropriate resolution. The UV-curable material 910 is developed to remove the uncured part 911. The substrate 920 and the cured parts 912 may be baked at 120° C. for 10 minutes in order to increase adhesion of the micro-lightguides 100 to the substrate 920.

In a certain embodiment, in which the substrate 920 may be a transparent material, the substrate 920 may be spin-cleaned with acetone/2-propanol and then baked at 200° C. for 5 minutes and cooled to room temperature before spin coating with UV-curable material 910. Alternatively, the substrate 920 may be cleaned via plasma cleaning with oxygen or ozone. After spin coating the UV-curable material 910 on to the substrate 920, the substrate 920 may be baked at 80° C. for 2 minutes to improve adhesion. The UV-curable material 910 may then be exposed to UV light with a conical irradiation profile. In a certain embodiment the UV light is collimated using an array of micro-lenses 1110 such that the UV light incident on the UV-curable material has a conical irradiation profile. The dose of IV exposure may be below 1000 mJ cm⁻² in order to achieve appropriate resolution. After exposure the UV-curable material 910 is developed to remove the uncured part 913. The substrate 920 and the cured parts 914 may be baked at 120° C. for 10 minutes in order to increase adhesion of the micro-lightguides 100 to the substrate 920.

1. A method for fabricating a frusto-conical micro-lightguide for collimation of light emitted from micro-LEDs, comprising:
depositing a layer of UV-curable material onto a substrate;
selectively curing a first part of the layer using UV light having a conical irradiation profile to define a shape of the frusto-conical micro-lightguide;
developing the UV-curable material to remove one of the first part of the layer and a second part of the layer, wherein the second part of the layer is uncured.

2. The method of claim 1, wherein the second part of the layer is removed and the first part of the layer comprises the frusto-conical micro-lightguide.

3. The method of claim 1, wherein the first part of the layer is removed and the second part of the layer comprises a frusto-conical recess that defines the shape of the frusto-conical micro-lightguide.

4. The method of claim 3, wherein the method further comprises depositing a lightguide material in the frusto-conical recess and removing the second part of the layer, such that the lightguide material comprises the frusto-conical micro-lightguide.

5. The method of claim 1, wherein the frusto-conical micro-lightguide comprises a first planar surface and a second planar surface, wherein the first planar surface has a smaller area than the second planar surface.

6. The method of claim 1, wherein the method further comprises fabricating an array of micro-lightguides.

7. The method of claim 1, wherein the conical irradiation profile takes a form of a substantially inverted cone and is achieved by transmitting the UV light through a mask that is moving in a circular trajectory, such that a first planar surface of the frusto-conical micro-lightguide is proximate the substrate.

8. The method of claim 7, wherein the substrate is a processed wafer comprising a plurality of micro-LEDs.

9. The method of claim 7, wherein the mask comprises one or more circular apertures.

10. The method of claim 1, wherein the frusto-conical micro-lightguide comprises a first planar surface and a second planar surface and wherein the conical irradiation profile is achieved by collimation of the UV light such that the second planar surface of the frusto-conical micro-lightguide is proximate the substrate.

11. The method of claim 10, wherein the collimation is achieved using one or more micro-lenses.

12. The method of claim 10, wherein the substrate is a transparent material such as glass or sapphire.

13. The method of claim 10, wherein the micro-lightguides are coupled to an array of micro-LEDs.

14. The method of claim 1, wherein the angle of a sidewall of the frusto-conical micro-lightguide to a central axis of the frusto-conical micro-lightguide is preferably between 10° and 18°, wherein the frusto-conical micro-lightguide comprises a first planar surface and a second planar surface, and wherein the central axis of the frusto-conical micro-lightguide passes through a central point of the first planar surface and a central point of the second planar surface.

15. The method of claim 1, wherein the central axis of the frusto-conical micro-lightguide is aligned with a central axis of a micro-LED.

16. The method of claim 1, wherein the micro-lightguide further comprises a reflective coating.

17. The method of claim 1, wherein the UV-curable material is deposited by spin coating.

18. The method of claim 5, wherein the first planar surface has a characteristic dimension that is 50% of a characteristic dimension of the second planar surface.

19. The method of claim 5, wherein the characteristic dimension of the second planar surface is equal to a characteristic dimension of the frusto-conical micro-lightguide that is parallel to the central axis of the frusto-conical micro-lightguide.

20. The method of claim 5, wherein the characteristic dimension of the first planar surface is 60% larger than a characteristic dimension of the micro-LED.

21. (canceled)
